(19) United States
(12) Patent Application Publication
(10) Pub. No.: US 2026/0143908 A1
(43) Pub. Date: May 21, 2026

(54) ORGANIC LIGHT EMITTING ELEMENT

(71) Applicant: TAIZHOU GUANYU TECHNOLOGY CO., LTD., ZHEJIANG PROVINCE (CN)

(72) Inventors: HUEI-SIOU CHEN, TAIPEI CITY (TW); KUO-CHENG HSU, TAICHUNG CITY (TW); YICHANG WANG, ZHEJIANG PROVINCE (CN)

(21) Appl. No.: 19/370,794

(22) Filed: Oct. 28, 2025

Related U.S. Application Data
(60) Provisional application No. 63/722,081, filed on Nov. 19, 2024.

(30) Foreign Application Priority Data
Nov. 15, 2024 (CN) 202411640509.2
Aug. 29, 2025 (CN) 202511231925.1

(51) Int. Cl. H10K 50/852; H10K 102/10

(52) U.S. Cl. CPC H10K 50/852; H10K 2102/101

(57) ABSTRACT

An organic light emitting element includes a substrate, an electrode, a semi-reflective surface, a fully reflective surface, and an organic light emitting layer. The electrode is disposed on the substrate. The organic light emitting layer is disposed between the semi-reflective surface and the fully reflective surface. A distance between the semi-reflective surface and the fully reflective surface defines an optical cavity length of a micro resonance cavity, a half wavelength of light emitted from the organic light emitting layer is N1 times a cavity length of a first order resonance cavity of the organic light emitting element, and N1 is equal to or greater than 1 and less than 1.6.

### PRIORITY CLAIM AND CROSS-REFERENCE

This application claims the benefit of U.S. Provisional Application No. 63/722,081, filed on Nov. 19, 2024, and claims priority to China Patent Application Serial No. 202411640509.2, filed on Nov. 15, 2024, and China Patent Application Serial No. 202511231925.1, filed on Aug. 29, 2025, the entirety of which are incorporated by reference herein.

### TECHNICAL FIELD

The disclosure relates to an organic light emitting element. More particularly, the disclosure relates to an organic light emitting element including an organic light emitting diode (OLED) structure.

### BACKGROUND

Currently, fine metal mask (FMM) is commonly used to coat light emitting layers of organic light emitting elements, or white light with color filters is used for the process. The pixel fineness or resolution produced by the above-mentioned processes is unsatisfactory.

### SUMMARY

In this disclosure, an organic light emitting element includes a substrate, an electrode, a semi-reflective surface, a fully reflective surface, and an organic light emitting layer. The electrode is disposed on the substrate. The organic light emitting layer is disposed between the semi-reflective surface and the fully reflective surface. A distance between the semi-reflective surface and the fully reflective surface defines an optical cavity length of a micro resonance cavity, a half wavelength of light emitted from the organic light emitting layer is N1 times a cavity length of a first order resonance cavity of the organic light emitting element, and N1 is equal to or greater than 1 and less than 1.6.

In this disclosure, an organic light emitting element includes a substrate, an electrode, a semi-reflective surface, a fully reflective surface, and an organic light emitting layer. The electrode is disposed on the substrate. The organic light emitting layer is disposed between the semi-reflective surface and the fully reflective surface. A distance between the semi-reflective surface and the fully reflective surface defines an optical cavity length of a micro resonance cavity, a wavelength of light emitted from the organic light emitting layer is N2 times a cavity length of a second order resonance cavity of the organic light emitting element, and N2 is equal to or greater than 1 and less than 1.4.

In some embodiments, when the organic light emitting layer emits red light, N1 is Nr, and when the organic light emitting layer emits green light, N1 is Nb, wherein Nb is greater than Nr.

In some embodiments, the organic light emitting element further includes a reflective layer disposed on the substrate, and the reflective layer includes the semi-reflective surface, wherein Nb is 1 to 1.42 times Nr.

In some embodiments, the organic light emitting element further includes a reflective layer disposed on the substrate, and the reflective layer includes a metal, wherein when the organic light emitting layer emits red light, N1 is equal to or greater than 1.12 and equal to or less than 1.34, and when the organic light emitting layer emits green light, N1 is equal to or greater than 1.32 and equal to or less than 1.58.

In some embodiments, the organic light emitting element further includes a reflective layer disposed on the substrate, and the reflective layer includes a dielectric, wherein when the organic light emitting layer emits red light, N1 is equal to or greater than 1.00 and equal to or less than 1.17, and when the organic light emitting layer emits green light, N1 is equal to or greater than 1.02 and equal to or less than 1.23.

In some embodiments, the electrode includes a transparent conductive material.

In some embodiments, the substrate includes a transparent material.

In some embodiments, for the light emitted from the organic light emitting layer, the semi-reflective surface has a reflectance greater than 20% and less than 80%, and the fully reflective surface has a reflectance greater than 90%.

In some embodiments, the organic light emitting element further includes a reflective layer disposed on the substrate, and the reflective layer includes a composite metal, wherein when the organic light emitting layer emits red light, N2 is equal to or greater than 1.05 and equal to or less than 1.24.

In some embodiments, the organic light emitting element further includes a reflective layer disposed on the substrate, and the reflective layer includes a composite metal, wherein when the organic light emitting layer emits green light, N2 is equal to or greater than 1.12 and equal to or less than 1.33.

In some embodiments, the organic light emitting element further includes a reflective layer disposed on the substrate, and the reflective layer includes a plurality of pairs of non-conductive material layers, wherein when the organic light emitting layer emits red light, N2 is equal to or greater than 1.00 and equal to or less than 1.19.

In some embodiments, the organic light emitting element further includes a reflective layer disposed on the substrate, and the reflective layer includes a plurality of pairs of non-conductive material layers, wherein when the organic light emitting layer emits green light, N2 is equal to or greater than 1.04 and equal to or less than 1.24.

In some embodiments, the electrode is a metal electrode.

In some embodiments, the electrode is a transparent electrode.

In some embodiments, for the light emitted from the organic light emitting layer, the semi-reflective surface has a transmittance less than 80% and greater than 20%, and the fully reflective surface has a transmittance less than 10%.

In some embodiments, the organic light emitting layer includes one of a hole injection layer, a hole transport layer, an organic emissive layer, an electron transport layer, or an electron injection layer.

### BRIEF DESCRIPTION OF THE DRAWINGS

To optimize understanding for the reader, it is recommended that the accompanying drawings and detailed descriptions with respect thereto be consulted while reading the disclosure. It should be noted that, in accordance with standard practices in the industry, various features are not drawn to scale. In fact, the dimensions of various features may be intentionally enlarged or reduced for illustration clarity.

FIG. 1 is a top view exemplarily showing an intermediate product of an organic light emitting element.

FIG. 2 is a cross sectional view of an organic light emitting element according to some embodiments.

FIG. 3 shows simulation results of emission peak spectra of an organic light emitting element according to some embodiments.

FIG. 4 shows simulation results of emission peak spectra of an organic light emitting element according to some embodiments.

FIG. 5 shows simulation results of emission peak spectra of an organic light emitting element according to some embodiments.

FIG. 6 is a cross sectional view of an organic light emitting element according to some embodiments.

FIG. 7 is a cross sectional view of an organic light emitting element according to some embodiments.

FIG. 8 is a cross sectional view of an organic light emitting element according to some embodiments.

FIG. 9 is a cross sectional view of an organic light emitting element according to some embodiments.

### DETAILED DESCRIPTION

Various embodiments or examples are provided in the following content for implementing different features of the present application. Specific examples of components and arrangements are described below to simplify the disclosure of the present application. Of course, these examples are provided for illustrative purposes only and are not intended to limit the present application.

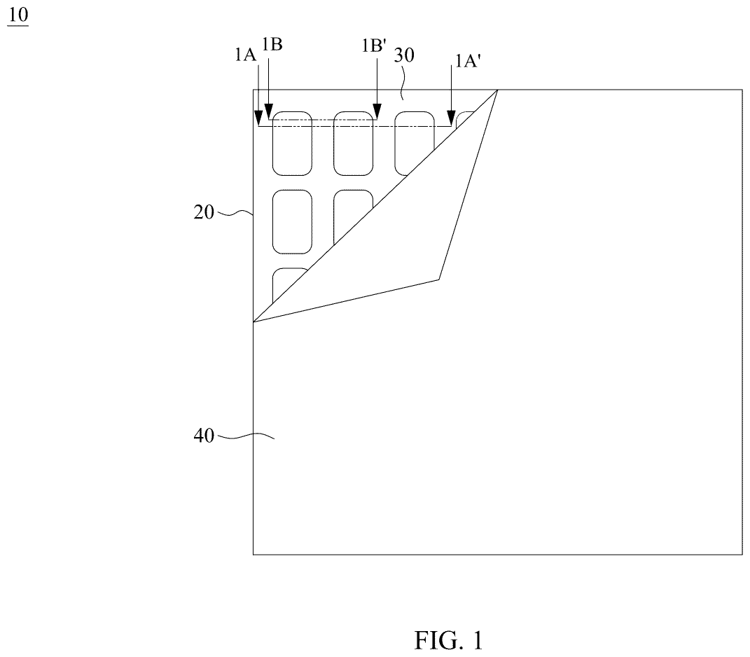

FIG. 1 is a top view exemplarily showing an intermediate product of an organic light emitting element 10. The organic light emitting element 10 has a light emitting layer 20 and a covering layer 40 disposed on the light emitting layer 20. For the light emitting layer 20, a spacer structure 30 may be designed to provide a recess array for accommodating a light emitting pixel array. In some embodiments, the spacer structure 30 may include a light sensitive material.

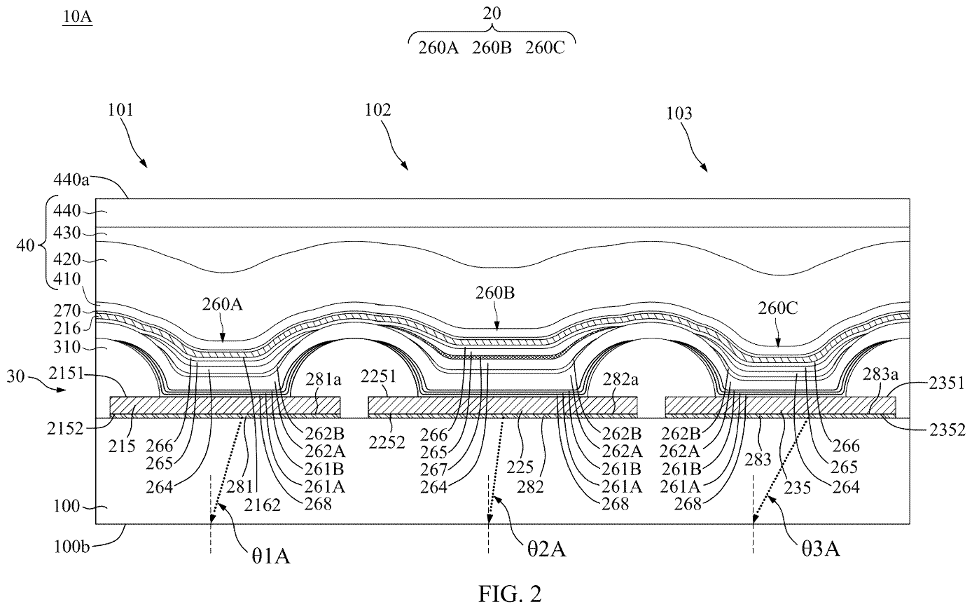

FIG. 2 is a cross sectional view exemplarily showing an organic light emitting element 10A. In some embodiments, FIG. 2 is a cross sectional view exemplarily taken along line 1A-1A′ in FIG. 1. In some embodiments, FIG. 2 is a cross sectional view exemplarily taken along line 1A-1A′ in FIG. 1 and illustrating only a light emitting region. The spacer structure 30 has several protrusions 310 to define a light emitting pixel pattern. A recess is disposed between two adjacent protrusions 310 and provides space for accommodating a light emitting pixel. One skilled in the art should understand that the protrusions 310 are shown to be disconnected in the cross sectional view of FIG. 2, but they are shown to be connectable to each other through other portions of the spacer structure 30 in the top view of FIG. 1.

As shown in FIG. 2, in some embodiments, the organic light emitting element 10 is, for example, a light emitting device including an organic light emitting diode (OLED) structure. In some embodiments, the organic light emitting element 10 includes a plurality of organic light emitting units (also referred to as light emitting pixels), for example, includes at least an organic light emitting unit 101, an organic light emitting unit 102, and an organic light emitting unit 103. In some embodiments, the organic light emitting units 101, 102, and 103 are located between the protrusion 310 and above a substrate 100. The organic light emitting units 101, 102, and 103 may emit light of the same wavelength or light of different wavelengths.

In some embodiments, the organic light emitting element 10 includes a substrate 100, an electrode 215, an electrode 225, an electrode 235, an electrode 216, the light emitting layer 20, an inorganic barrier layer 268, an inorganic barrier layer 270, a reflective layer 281, a reflective layer 282, a reflective layer 283, the spacer structure 30, and the covering layer 40.

In some embodiments, the substrate 100 may include a transistor array arranged corresponding to the light emitting pixels in the light emitting layer 20. The substrate 100 may include several capacitors. In some embodiments, more than one transistor is arranged together with a capacitor and a light emitting pixel to form a circuit. In some embodiments, the substrate 100 may include a glass substrate or a silicon substrate.

In some embodiments, the electrode 215, the electrode 225, and the electrode 235 are disposed on the substrate 100. In some embodiments, the electrode 215, the electrode 225, and the electrode 235 are anodes. In some embodiments, the electrode 215, the electrode 225, and the electrode 235 include a metal material, such as Ag, Al, Mg, Au, AlCu alloy, AgMo alloy, or the like. In some embodiments, the electrode 215, the electrode 225, and the electrode 235 include indium tin oxide (ITO), indium zinc oxide (IZO), or any other suitable material.

In some embodiments, the light emitting layer 20 includes an organic light emitting layer 260A, an organic light emitting layer 260B, and an organic light emitting layer 260C. In some embodiments, the organic light emitting layer 260A is disposed on the electrode 215, the organic light emitting layer 260B is disposed on the electrode 225, and the organic light emitting layer 260C is disposed on the electrode 235. In some embodiments, a thickness of the organic light emitting layer 260A, a thickness of the organic light emitting layer 260B, and a thickness of the organic light emitting layer 260C are all different. In some embodiments, the thickness of the organic light emitting layer 260B is greater than the thickness of the organic light emitting layer 260A, and the thickness of the organic light emitting layer 260A is greater than the thickness of the organic light emitting layer 260C.

In some embodiments, the organic light emitting layers 260A, 260B, and 260C emit light of the same color or light of different colors. In some embodiments, a wavelength of light emitted from the organic light emitting layer 260B is greater than a wavelength of light emitted from the organic light emitting layer 260A, and the wavelength of light emitted from the organic light emitting layer 260A is greater than a wavelength of light emitted from the organic light emitting layer 260C. In some embodiments, the organic light emitting layer 260A emits green light, the organic light emitting layer 260B emits red light, and the organic light emitting layer 260C emits blue light.

In some embodiments, organic material layers of the organic light emitting layers 260A, 260B, and 260C include an organic material, which may be disposed in any of the organic material layers of the organic light emitting layers 260A, 260B, and 260C based on different implementations. In some embodiments, the organic material has an absorptivity equal to or greater than 50% for a specific wavelength. In some embodiments, the organic material has an absorptivity equal to or greater than 60% for a specific wavelength. In some embodiments, the organic material has an absorptivity equal to or greater than 70% for a specific wavelength. In some embodiments, the organic material has an absorptivity equal to or greater than 80% for a specific wavelength. In some embodiments, the organic material has an absorptivity equal to or greater than 90% for a specific wavelength. In some embodiments, the organic material has an absorptivity equal to or greater than 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2, in some embodiments, the organic light emitting unit 101 includes the electrode 215, the organic light emitting layer 260A, and the electrode 216. In some embodiments, the organic light emitting layer 260A includes a plurality of organic material layers, such as a hole injection layer (HIL) 261A, a hole injection layer 261B, a hole transport layer (HTL) 262A, a hole transport layer 262B, an organic emissive layer (EM) 264, an electron transport layer (ETL) 265, and an electron injection layer (EIL) 266. In some embodiments, the electrode 216 is disposed above the organic light emitting layer structure 260A.

In some embodiments, the organic light emitting unit 102 includes the electrode 225, the organic light emitting layer 260B, and the electrode 216. In some embodiments, the organic light emitting layer 260B includes a plurality of organic material layers, such as a hole injection layer 261A, a hole injection layer 261B, a hole transport layer 262A, a hole transport layer 262B, an organic emissive layer 264, a hole blocking layer (HBL) 267, an electron transport layer 265, and an electron injection layer 266. In some embodiments, the electrode 216 is disposed above the organic light emitting layer structure 260B.

In some embodiments, the organic light emitting unit 103 includes the electrode 235, the organic light emitting layer 260C, and the electrode 216. In some embodiments, the organic light emitting layer 260C includes a plurality of organic material layers, such as a hole injection layer 261A, a hole injection layer 261B, a hole transport layer 262A, a hole transport layer 262B, an organic emissive layer 264, an electron transport layer 265, and an electron injection layer 266. In some embodiments, the electrode 216 is disposed above the organic light emitting layer 260C.

In some embodiments, the electrode 216 contacts the organic light emitting layers 260A, 260B, and 260C. The electrode 216 may be a continuous film as shown in FIG. 2 and is disposed above the organic light emitting layers 260A, 260B, and 260C and the protrusions 310. In some embodiments, the electrodes 216 may be further disposed on the spacer structure 30. In some embodiments, the electrode 216 is a common electrode for all light emitting pixels in the light emitting layer 20. In some embodiments, the electrode 216 includes a metal material, such as Ag, Al, Mg, Au, AlCu alloy, AgMo alloy, or the like. In some embodiments, the electrode 216 includes ITO, IZO, or any other suitable material. In other words, the electrode 216 is a common electrode for several organic light emitting units. In some embodiments, the electrode 216 is a common electrode for all organic light emitting units in the organic light emitting element 10A.

In some embodiments, the reflective layer 281 is disposed between the substrate 100 and the electrode 215. In some embodiments, a surface 2151 of the electrode 215 faces the electrode 216, and a surface 2152 of the electrode 215 opposite the surface 2151 faces the substrate 100 and contacts the reflective layer 281. In some embodiments, the reflective layer 281 includes a reflective surface 281a (also referred to as a semi-reflective surface), the electrode 216 includes a surface 2162 (also referred to as a fully reflective surface, the reflective surface 281a faces the organic light emitting layer 260A, and the surface 2162 faces the organic light emitting layer 260A. In some embodiments, the electrode 215 is a transparent electrode, and the reflective surface 281a is used to further reflect the light emitted from the organic light emitting layer 260A. In some embodiments, the reflective surface 281a faces away from a light emitting surface of the organic light emitting element 10A (e.g., a lower surface 100b of the substrate 100), and the reflective surface 281a is closer to the light emitting surface of the organic light emitting element 10A than the surface 2162.

In some embodiments, for the light emitted from the organic light emitting layer 260A, the surface 2162 (or the fully reflective surface) has a reflectance greater than a reflectance of the reflective surface 281a (or the semi-reflective surface). In some embodiments, for the light emitted from the organic light emitting layer 260A, the reflective surface 281a has a reflectance greater than 20% and less than 80%, such as equal to or greater than 30%, equal to or greater than 40%, equal to or greater than 50%, equal to or greater than 60%, or equal to or greater than 70%. In some embodiments, for the light emitted from the organic light emitting layer 260A, the reflective surface 281a has a reflectance greater than 20% and less than 90%, such as equal to or greater than 30%, equal to or greater than 40%, equal to or greater than 50%, equal to or greater than 60%, or equal to or greater than 95%.

In some embodiments, for the light emitted from the organic light emitting layer 260A, the surface 2162 (or the fully reflective surface) has a transmittance less than a transmittance of the reflective surface 281a (or the semi-reflective surface). In some embodiments, for the light emitted from the organic light emitting layer 260A, the reflective surface 281a has a transmittance less than 80% and greater than 20%, such as equal to or less than 70%, equal to or less than 60%, equal to or less than 50%, equal to or less than 40%, or equal to or less than 30%. In some embodiments, for the light emitted from the organic light emitting layer 260A, the surface 2162 has a transmittance less than 10%, such as equal to or less than 5%.

In some embodiments, the reflective layer 282 is disposed between the substrate 100 and the electrode 225. In some embodiments, a surface 2251 of the electrode 225 faces the electrode 216, and a surface 2252 of the electrode 225 opposite the surface 2251 faces the substrate 100 and contacts the reflective layer 282. In some embodiments, the reflective layer 282 includes a reflective surface 282a (also referred to as a semi-reflective surface), and the reflective surface 282a faces the organic light emitting layer 260B. In some embodiments, the electrode 225 is a transparent electrode, and the reflective surface 282a is used to further reflect the light emitted from the organic light emitting layer 260B. In some embodiments, the reflective surface 282a faces away from the light emitting surface of the organic light emitting element 10A (e.g., the lower surface 100b of the substrate 100), and the reflective surface 282a is closer to the light emitting surface of the organic light emitting element 10A than the surface 2162 (or a fully reflective surface).

In some embodiments, for the light emitted from the organic light emitting layer 260B, the surface 2162 (or the fully reflective surface) has a reflectance greater than a reflectance of the reflective surface 282a (or the semi-reflective surface). In some embodiments, for the light emitted from the organic light emitting layer 260B, the reflective surface 282a has a reflectance greater than 20% and less than 80%, such as equal to or greater than 30%, equal to or greater than 40%, equal to or greater than 50%, equal to or greater than 60%, or equal to or greater than 70%. In some embodiments, for the light emitted from the organic light emitting layer 260B, the surface 2162 has a reflectance greater than 90%, such as equal to or greater than 95%.

In some embodiments, for the light emitted from the organic light emitting layer 260B, the surface 2162 (or the fully reflective surface) has a transmittance less than a transmittance of the reflective surface 282a (or the semi-reflective surface). In some embodiments, for the light emitted from the organic light emitting layer 260B, the reflective surface 282a has a transmittance less than 80% and greater than 20%, such as equal to or less than 70%, equal to or less than 60%, equal to or less than 50%, equal to or less than 40%, or equal to or less than 30%. In some embodiments, for the light emitted from the organic light emitting layer 260B, the surface 2162 has a transmittance less than 10%, such as equal to or less than 5%.

In some embodiments, the reflective layer 283 is disposed between the substrate 100 and the electrode 235. In some embodiments, a surface 2351 of the electrode 235 faces the electrode 216, and a surface 2352 of the electrode 235 opposite the surface 2351 faces the substrate 100 and contacts the reflective layer 283. In some embodiments, the reflective layer 283 includes a reflective surface 283a (also referred to as a semi-reflective surface), and the reflective surface 283a faces the organic light emitting layer 260C. In some embodiments, the electrode 235 is a transparent electrode, and the reflective surface 283a is used to further reflect the light emitted from the organic light emitting layer 260C. In some embodiments, the reflective surface 283a faces away from the light emitting surface of the organic light emitting element 10A (e.g., the lower surface 100b of the substrate 100), and the reflective surface 283a is closer to the light emitting surface of the organic light emitting element 10A than the surface 2162 (or a fully reflective surface).

In some embodiments, for the light emitted from the organic light emitting layer 260C, the surface 2162 (or the fully reflective surface) has a reflectance greater than a reflectance of the reflective surface 283a (or the semi-reflective surface). In some embodiments, for the light emitted from the organic light emitting layer 260C, the reflective surface 283a has a reflectance greater than 20% and less than 80%, such as equal to or greater than 30%, equal to or greater than 40%, equal to or greater than 50%, equal to or greater than 60%, or equal to or greater than 70%. In some embodiments, for the light emitted from the organic light emitting layer 260C, the surface 2162 has a reflectance greater than 90%, such as equal to or greater than 95%.

In some embodiments, for the light emitted from the organic light emitting layer 260C, the surface 2162 (or the fully reflective surface) has a transmittance less than a transmittance of the reflective surface 283a (or the semi-reflective surface). In some embodiments, for the light emitted from the organic light emitting layer 260C, the reflective surface 283a has a transmittance less than 80% and greater than 20%, such as equal to or less than 70%, equal to or less than 60%, equal to or less than 50%, equal to or less than 40%, or equal to or less than 30%. In some embodiments, for the light emitted from the organic light emitting layer 260C, the surface 2162 has a transmittance less than 10%, such as equal to or less than 5%.

In some embodiments, each of the reflective layers 281, 282, and 283 includes a metal (or a reflective metal), a dielectric (or a non-conductive reflective material), or any other suitable material. In some embodiments, each of the reflective layers 281, 282, and 283 includes a composite metal, a distributed Bragg reflector (DBR), or any other suitable reflective material. In some embodiments, each of the reflective layers 281, 282, and 283 includes a magnesium-silver composite. In some embodiments, each of the reflective layers 281, 282, and 283 includes a plurality of pairs of non-conductive material layers, and a refractive index difference between each pair of non-conductive material layers is equal to or greater than 0.2, such as equal to or greater than 0.4. In some embodiments, the greater the thickness of a reflective metal, the higher the reflectance of the reflective metal. In some embodiments, the more layers in a DBR, the higher the reflectance of the DBR.

In some embodiments, a distance between the semi-reflective surface (e.g., the reflective layer 281, 282, or 283) and the fully reflective surface (e.g., the surface 2162 of the electrode 216 facing the organic light emitting layers 260A, 260B, and 260C) constitutes or defines an optical cavity length (also referred to as a of a cavity length) of a microcavity or a micro resonance cavity. In some embodiments, as shown in FIG. 2, light emitted from a resonance cavity (or a microcavity or a micro resonance cavity) has a specific angle with a normal line of the light emitting surface 100b to achieve better luminous efficacy. The angle varies depending on a wavelength of the light. In some embodiments, light emitted from a resonance cavity of the organic light emitting unit 101 has an angle θ1A with the normal line of the light emitting surface, light emitted from a resonance cavity of the organic light emitting unit 102 has an angle θ2A with the normal line of the light emitting surface, and light emitted from a resonance cavity of the organic light emitting unit 103 has an angle θ3A with the normal line of the light emitting surface. In some embodiments, at least two of the angle θ1A, the angle θ2A, and the angle θ3A are different from each other.

In some embodiments, a half wavelength of light emitted from an organic light emitting layer is N1 times a cavity length of a first order resonance cavity of the organic light emitting element, and N1 is equal to or greater than 1 and less than 1.6. In some embodiments, when the organic light emitting layer emits red light (λ=620 nm), N1 is Nr, and when the organic light emitting layer emits green light (λ=525 nm), N1 is Nb, wherein Nb is greater than Nr. In some embodiments, Nb is about 1 to about 1.42 times Nr. In some embodiments, when the reflective layer includes a metal, Nb is about 1 to about 1.42 times Nr, such as about 1.17 times Nr. In some embodiments, when the reflective layer includes a dielectric, Nb is about 1 to about 1.23 times Nr, such as about 1.05 times Nr.

In some embodiments, when the reflective layer includes a metal and the organic light emitting layer emits red light, N1 is equal to or greater than 1.12 and equal to or less than 1.34. In some embodiments, when the reflective layer includes a metal and the organic light emitting layer emits green light, N1 is equal to or greater than 1.32 and equal to or less than 1.58. In some embodiments, when the reflective layer includes a dielectric and the organic light emitting layer emits red light, N1 is equal to or greater than 1.00 and equal to or less than 1.17. In some embodiments, when the reflective layer includes a dielectric and the organic light emitting layer emits green light, N1 is equal to or greater than 1.02 and equal to or less than 1.23.

In some embodiments, a wavelength of light emitted from an organic light emitting layer is N2 times a cavity length of a second order resonance cavity of the organic light emitting element, and N2 is equal to or greater than 1 and less than 1.4. The first order resonance cavity and the second order resonance cavity have different cavity length, i.e., thicknesses. The thickness of the second order resonance cavity is twice the thickness of the first order resonance cavity, and thus the second order resonance cavity has more stable performance more stably under high temperature or high current density.

In some embodiments, when the organic light emitting layer emits red light (λ=620 nm), N2 is Nr, and when the organic light emitting layer emits green light (λ=525 nm), N2 is Nb, wherein Nb is greater than Nr. In some embodiments, Nb is about 1 to about 1.27 times Nr. In some embodiments, when the reflective layer includes a metal, Nb is about 1 to about 1.27 times Nr, such as about 1.07 times Nr. In some embodiments, when the reflective layer includes a dielectric, Nb is about 1 to about 1.24 times Nr, such as about 1.04 times Nr.

In some embodiments, when the reflective layer includes a metal and the organic light emitting layer emits red light, N2 is equal to or greater than 1.05 and equal to or less than 1.24. In some embodiments, when the reflective layer includes a metal and the organic light emitting layer emits green light, N2 is equal to or greater than 1.12 and equal to or less than 1.33. In some embodiments, when the reflective layer includes a dielectric and the organic light emitting layer emits red light, N2 is equal to or greater than 1.00 and equal to or less than 1.19. In some embodiments, when the reflective layer includes a dielectric and the organic light emitting layer emits green light, N2 is equal to or greater than 1.04 and equal to or less than 1.24.

It can be seen that, compared to the cases including a dielectric, the reflective layer has a larger N1 or N2 when including a metal, and thus enables shrinking the optical cavity length and obtaining higher brightness. The larger N1 or N2 when the reflective layer includes a metal is related to the phase difference when an electromagnetic wave is reflected at the interface between different materials.

On the other hand, a dielectric has lower optical loss than a metal and provides a better resonance effect, and thus it is more suitable as a reflective layer. In addition, a dielectric is more stable under high temperature operation or high temperature storage, and thus a higher yield can be achieved.

Some embodiments of the disclosure herein are listed in Tables 1 and 2.

TABLE 1

| | Resonance Cavity Order | | | |
|---|---|---|---|---|
| | First Order Resonance Cavity (λ/2) | | | |
| | Reflective Layer Material | | | |
| | Metal | | Dielectric | |
| Wavelength (nm) | 620 | 525 | 620 | 525 |
| Optical Cavity | 232-275 | 166-198 | 264-314 | 214-255 |
| Length (nm) | | | | |
| N1 | 1.34-1.12 | 1.58-1.32 | 1.17-1.00 | 1.23-1.02 |
| HTL/ETL | 1-5 | 1-5 | 1-5 | 1-5 |
| Thickness | | | | |
| Ratio | | | | |

TABLE 2

| | Resonance Cavity Order | | | |
|---|---|---|---|---|
| | First Order Resonance Cavity (λ/2) | | | |
| | Reflective Layer Material | | | |
| | Metal | | Dielectric | |
| Wavelength (nm) | 620 | 525 | 620 | 525 |
| Optical Cavity | 469-590 | 395-469 | 520-617 | 424-504 |
| Length (nm) | | | | |
| N1 | 1.24-1.05 | 1.33-1.12 | 1.19-1.00 | 1.24-1.04 |
| HTL/ETL | 1-5 | 1-5 | 1-5 | 1-5 |
| Thickness | | | | |
| Ratio | | | | |

In some embodiments, the spacer structure 30 is disposed on the substrate 100 and partially covers the electrodes 215, 225, and 235. In some embodiments, the spacer structure 30 is disposed between the organic light emitting layers 260A, 260B, and 260C. In some embodiments, the spacer structure 30 may comprise the protrusions 310. In some embodiments, a pattern of the spacer structure 30 is designed based on a pixel arrangement. In some embodiments, the spacer structure 30 is used as a pixel defined layer (PDL). In some embodiments, the protrusions 310 define pixel regions. In some embodiments, each protrusion 310 fills into a gap between adjacent two of the electrodes 215, 225, and 235. Each of the electrodes 215, 225, and 235 is partially covered by the protrusions 310. In some embodiments, the spacer structure 30 includes an organic insulating material. In some embodiments, the spacer structure 30 includes a light sensitive material. In some embodiments, the spacer structure 30 may further include quantum dots having excellent light absorption efficiency. In some embodiments, the spacer structure 30 may further include a carbon black material, such as carbon black nanoparticles, conductive fibers containing carbon black, or the like. In some embodiments, the spacer structure 30 may further include a black body material having an absorptivity of 90%, 95%, 99%, 99.5%, or equal to or more than 99.9% for visible light.

In some embodiments, the spacer structure 30 has an absorptivity equal to or greater than 50% for a specific wavelength. In some embodiments, the spacer structure 30 has an absorptivity equal to or greater than 60% for a specific wavelength. In some embodiments, the spacer structure 30 has an absorptivity equal to or greater than 70% for a specific wavelength. In some embodiments, the spacer structure 30 has an absorptivity equal to or greater than 80% for a specific wavelength. In some embodiments, the spacer structure 30 has an absorptivity equal to or greater than 90% for a specific wavelength. In some embodiments, the spacer structure 30 has an absorptivity equal to or greater than 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the covering layer 40 includes a capping layer 410, an encapsulation layer 420, a filling layer 430, and a cover plate 440. In some embodiments, the capping layer 410 is disposed on the electrode 216, and is substantially conformal to a non-planar upper surface of the electrode 216. The capping layer 410 may include a dielectric material or an inorganic insulating material, such as silicon oxide. In some embodiments, the capping layer 410 may include a hole transport layer material for extracting light lost inside the organic light emitting element to increase the light emitting efficiency. The capping layer 410 may also be referred to as a light extraction layer.

In some embodiments, the encapsulation layer 420 is disposed on the capping layer 410, and is substantially conformal to a non-planar upper surface of the capping layer 410. The encapsulation layer 420 may include an oxide, such as silicon oxide. In some embodiments, the encapsulation layer 420 is substantially conformal to the non-planar upper surface of the capping layer 410, and includes a plurality of recesses corresponding to the organic light emitting layers 260A, 260B, and 260C. The encapsulation layer 420 may include an organic polymer material, such as an epoxy-based material.

In some embodiments, the filling layer 430 is disposed on the encapsulation layer 420, and is substantially conformal to a non-planar upper surface of the encapsulation layer 420. The filling layer 430 may also be referred to as a planarization layer. The filling layer 430 may include an organic polymer material, such as an epoxy-based material.

In some embodiments, the cover plate 440 is disposed on a planar upper surface of the filling layer 430. The cover plate 440 may also be referred to as a protection layer. The cover plate 440 may include a transparent hard cover plate, such as a glass plate. The cover plate 440 may be used to prevent components of the organic light emitting element from being exposed to external moisture, which may lead to component failures and inability to emit light.

In some embodiments, the inorganic barrier layer 268 is disposed between the electrodes 215, 225, and 235 and the organic light emitting layers 260A, 260B, and 260C. In some embodiments, a side surface of the inorganic barrier layer 268 contacts a protrusion 310. In some embodiments, the inorganic barrier layer 268 substantially completely covers interfaces between the electrodes 215, 225, and 235 and the organic light emitting layers 260A, 260B, and 260C. In some embodiments, the inorganic barrier layer 268 includes a transition metal oxide. In some embodiments, the inorganic barrier layer 268 includes MoO₃. In some embodiments, the inorganic barrier layer 268 has a thickness equal to or less than 100 Å. In some embodiments, a ratio of the thickness of the inorganic barrier layer 268 to a thickness of the electrodes 215, 225, and 235 is less than 0.1, 0.06, or 0.03. In some embodiments, the inorganic barrier layer 268 together with the hole injection layers 261A and 261B may constitute hole injection layers of the organic light emitting layers 260A, 260B, and 260C.

In some embodiments, the inorganic barrier layer 270 contacts the capping layer 410. In some embodiments, the inorganic barrier layer 270 covers the electrode 216. In some embodiments, the capping layer 410 is disposed on the inorganic barrier layer 270, and separated from the electrode 216 by the inorganic barrier layer 270. In some embodiments, the inorganic barrier layer 270 substantially completely covers an interface between the electrode 216 and the capping layer 410. In some embodiments, the inorganic barrier layer 270 includes a transition metal oxide. In some embodiments, the inorganic barrier layer 270 includes MoO₃. In some embodiments, the inorganic barrier layer 270 has a thickness equal to or less than 100 Å. In some embodiments, a ratio of the thickness of the inorganic barrier layer 270 to a thickness of the electrode 216 is less than 0.15, 0.1, or 0.05. In some embodiments, a ratio of the thickness of the inorganic barrier layer 270 to a thickness of the capping layer 410 is less than 0.5, 0.3, or 0.15.

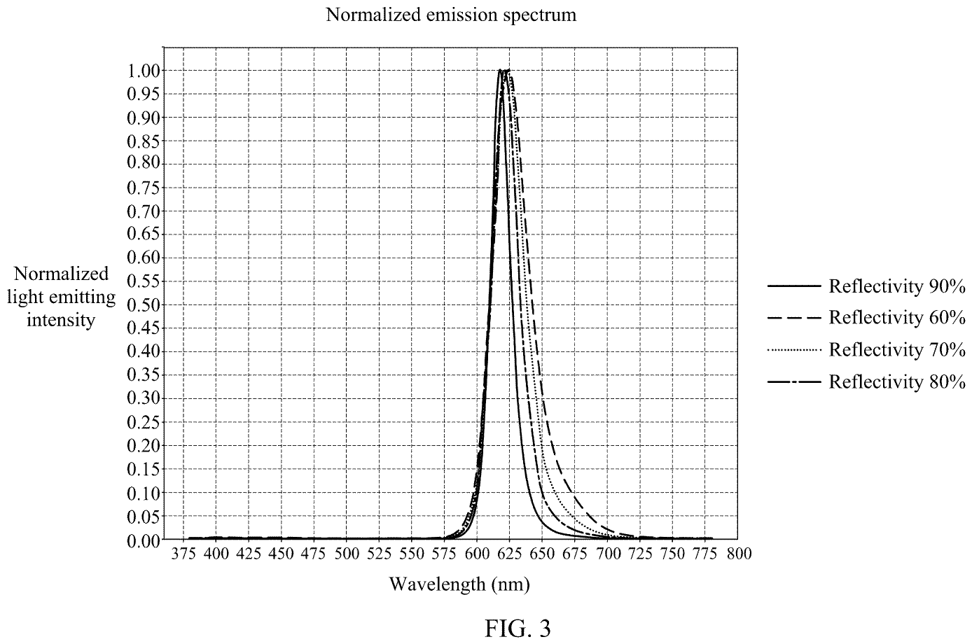

As shown in FIG. 3, with the design of the reflective layer, by using reflective layers of different materials, the intensity of the resonance cavity can be enhanced for the organic light emitting units of different colors, thereby narrowing the full width at half maximum (FWHM) of the emission peak, and thus enabling enhancement of color purity of emitted light and improvement of monochromaticity, and the first order cavity length of the resonance cavity can be made smaller than the half wavelength (λ/2) of the light emitted from the organic light emitting layer or the second order cavity length of the resonance cavity can be made smaller than the wavelength (λ) of the light emitted from the organic light emitting layer, thereby improving luminous efficacy and reducing the thickness of the entire structure of the organic light emitting element. In the case of FIG. 3, the reflective layer may include a dielectric, which has a better resonance effect.

Typically, when white light LEDs and a color filter are used to fabricate pixels of different colors, the optical cavity length of the microcavity or the resonance cavity is not specifically designed because colors of the emitted light are restricted by the color filter rather than being emitted directly from self-luminous organic light emitting layers. Furthermore, in the field of organic light emitting elements, it is generally believed by those skilled in the art tends to that the best brightness performance is achieved when different organic light emitting units are designed with cavity optical lengths corresponding to the half wavelengths of emitted light, for example, a red organic light emitting layer is designed to have a thickness of 3100 Å (half of 620 nm), a green organic light emitting layer is designed to have a thickness of 2625 Å (half of 525 nm), and a blue organic light emitting layer is designed to have a thickness of 2350 Å (half of 470 nm). However, according to some embodiments of the disclosure, when a cavity optical length (or a first order cavity length) is smaller than the half wavelength (λ/2) of the emitted light and the aforementioned condition for N1 is satisfied, the organic light emitting element can have better luminous efficacy. Furthermore, according to some embodiments of the disclosure, when a cavity optical length (or a second order cavity length) is smaller than the wavelength (λ) of the emitted light and the aforementioned condition for N2 is satisfied, the organic light emitting element can have better luminous efficacy.

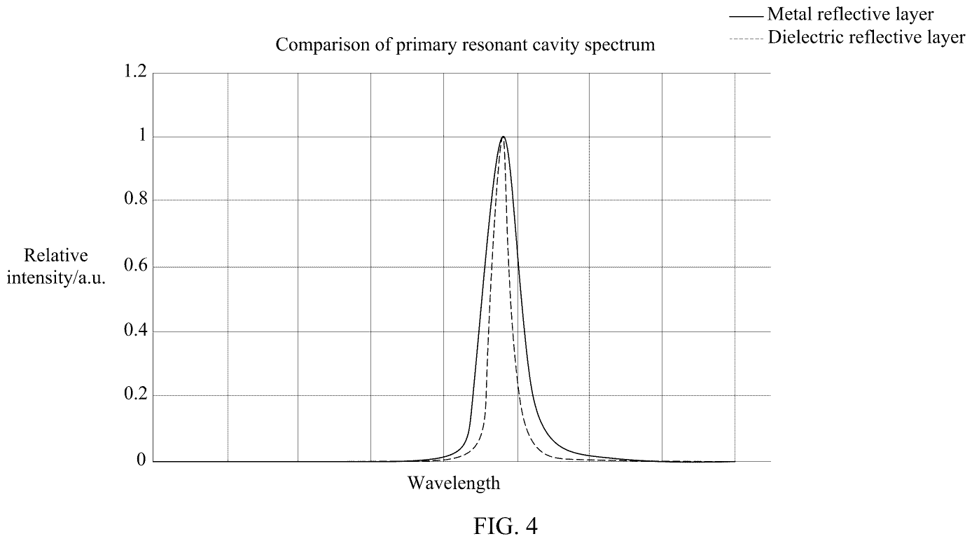

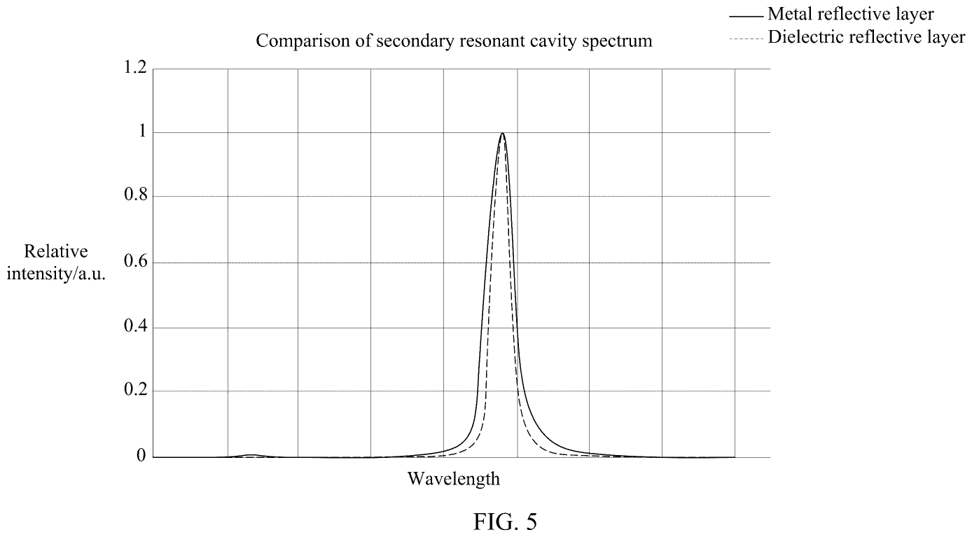

FIG. 4 shows FWHM simulation results of a dielectric reflective layer and a metal reflective layer of embodiments of a first order resonance cavity. FIG. 5 shows FWHM simulation results of a dielectric reflective layer and a metal reflective layer of embodiments of a second order resonance cavity. It can be seen from FIG. 4 and FIG. 5 that the FWHM of the dielectric is smaller than the FWHM of the metal, that is to say, resonance effect of a dielectric is more obvious than resonance effect of a metal, and color purity of a dielectric is higher than color purity of a metal.

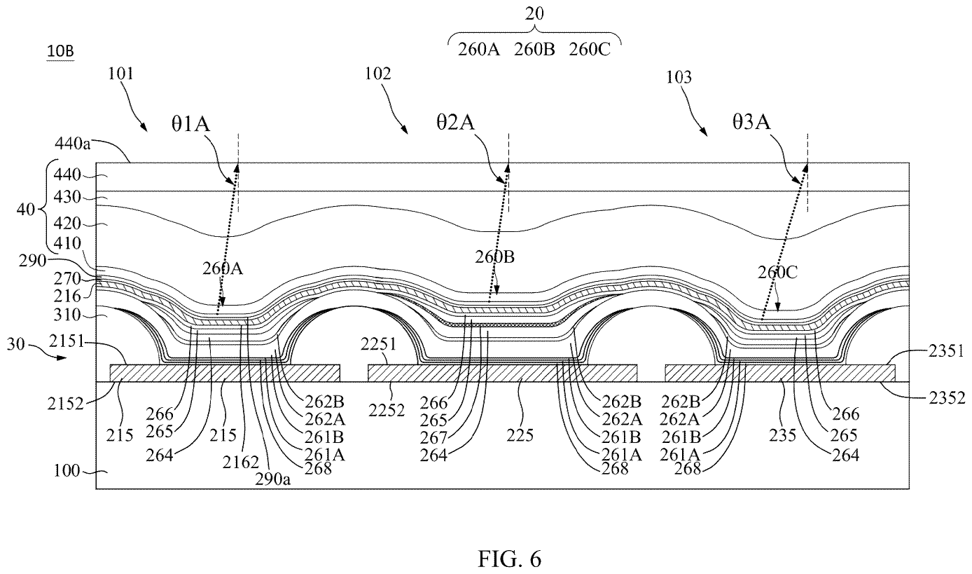

FIG. 6 is a cross sectional view exemplarily showing an organic light emitting element 10B. In some embodiments, FIG. 6 is a cross sectional view exemplarily showing the organic light emitting element 10 of FIG. 1. In some embodiments, FIG. 6 is a cross sectional view exemplarily taken along line 1A-1A′ in FIG. 1. In some embodiments, FIG. 6 is a cross sectional view exemplarily taken along line 1A-1A′ in FIG. 1 and illustrating only a light emitting region. FIG. 6 has a structure similar to the structure of FIG. 2, with a difference described as follows.

In some embodiments, the organic light emitting element 10B includes a reflective layer 290, the electrode 216 is a transparent electrode, and the reflective layer 290 is disposed between the capping layer 410 and the electrode 216. In some embodiments, the reflective layer 290 includes a non-conductive material, such as a distributed Bragg reflector (DBR). In some embodiments, the reflective layer 290 includes a plurality of pairs of non-conductive material layers, and a refractive index difference between each pair of non-conductive material layers is equal to or greater than 0.2, such as equal to or greater than 0.4. In some embodiments, the reflective layer 290 includes a reflective surface 290a (also referred to as a semi-reflective surface), the electrode 215 includes a surface 2151 (also referred to as a fully reflective surface) facing an organic light emitting layer, the electrode 225 includes a surface 2251 (also referred to as a fully reflective surface) facing an organic light emitting layer, and the electrode 235 includes a surface 2351 (also referred to as a fully reflective surface) facing an organic light emitting layer.

In some embodiments, the electrode 216 is a transparent electrode, and the reflective surface 290a is used to further reflect the light emitted from the organic light emitting layers 260A, 260B, and 260C. In some embodiments, a surface 2161 of the electrode 216 faces the capping layer 410 and contacts the reflective layer 290. In some embodiments, a surface 2162 of the electrode 216 faces the electrodes 215, 225, and 235. In some embodiments, the reflective surface 290a faces away from a light emitting surface of the organic light emitting element (e.g., a surface 440a of the cover plate 440), and the reflective surface 290a (or the semi-reflective surface) is closer to the light emitting surface of the organic light emitting element than the surfaces 2151, 2251, and 2351 (or the fully reflective surfaces).

In some embodiments, for the light emitted from the organic light emitting layers 260A, 260B, and 260C, the surfaces 2151, 2251, and 2351 (or the fully reflective surfaces) have a reflectance greater than a reflectance of the reflective surface 290a (or the semi-reflective surface). In some embodiments, for the light emitted from the organic light emitting layers 260A, 260B, and 260C, the reflective surface 290a has a reflectance greater than 20% and less than 80%, such as equal to or greater than 30%, equal to or greater than 40%, equal to or greater than 50%, equal to or greater than 60%, or equal to or greater than 70%. In some embodiments, for the light emitted from the organic light emitting layers 260A, 260B, and 260C, the surfaces 2151, 2251, and 2351 have a reflectance greater than 90%, such as equal to or greater than 95%.

In some embodiments, for the light emitted from the organic light emitting layers 260A, 260B, and 260C, the surfaces 2151, 2251, and 2351 (or the fully reflective surfaces) have a transmittance less than a transmittance of the reflective surface 290a (or the semi-reflective surface). In some embodiments, for the light emitted from the organic light emitting layers 260A, 260B, and 260C, the reflective surface 290a has a transmittance less than 80% and greater than 20%, such as equal to or less than 70%, equal to or less than 60%, equal to or less than 50%, equal to or less than 40%, or equal to or less than 30%. In some embodiments, for the light emitted from the organic light emitting layers 260A, 260B, and 260C, the surfaces 2151, 2251, and 2351 have a transmittance less than 10%, such as less than 5%.

A distance between the semi-reflective surface (e.g., the reflective surface 290a) and the fully reflective surface (e.g., the surfaces 2151, 2251, and 2351) constitutes or defines an optical cavity length (also referred to as a of a cavity length) of a microcavity or a micro resonance cavity. When the cavity length of the first order resonance cavity of the organic light emitting element 10B satisfies the aforementioned condition for N1 or the cavity length of the second order resonance cavity satisfies the aforementioned condition for N2, the luminous efficacy can be improved and the thickness of the entire structure of the organic light emitting element 10B can be reduced.

In some embodiments, as shown in FIG. 6, light emitted from a resonance cavity (or a microcavity or a micro resonance cavity) has a specific angle with a normal line of the light emitting surface to achieve better luminous efficacy. The angle varies depending on a wavelength of the light. In some embodiments, light emitted from a resonance cavity of the organic light emitting unit 101 has an angle θ1A with the normal line of the light emitting surface, light emitted from a resonance cavity of the organic light emitting unit 102 has an angle θ2A with the normal line of the light emitting surface, and light emitted from a resonance cavity of the organic light emitting unit 103 has an angle θ3A with the normal line of the light emitting surface. In some embodiments, at least two of the angle θ1A, the angle θ2A, and the angle θ3A are different from each other.

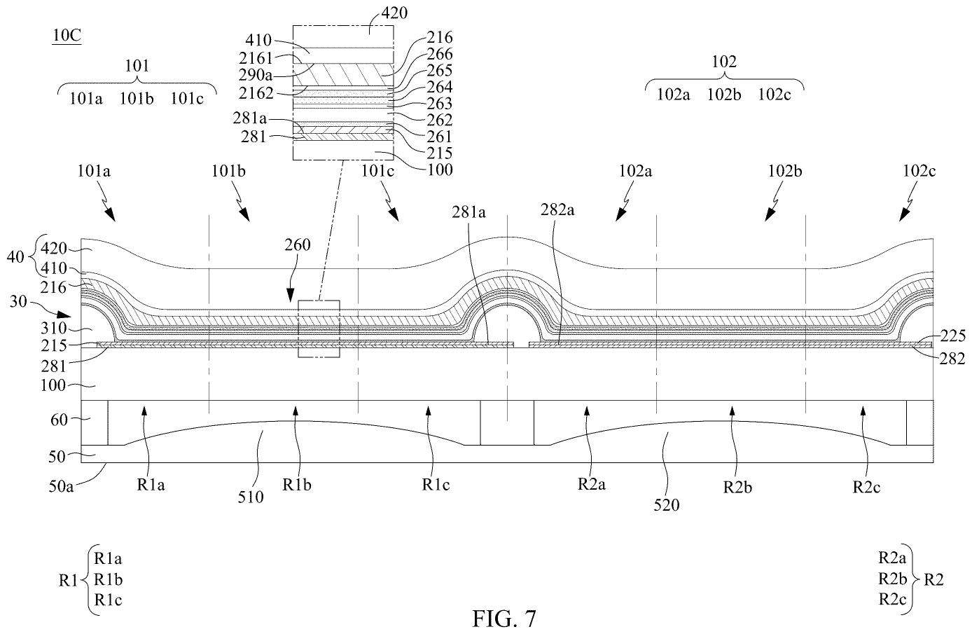

FIG. 7 is a cross sectional view exemplarily showing an organic light emitting element 10C. In some embodiments, FIG. 7 is a cross sectional view exemplarily showing the organic light emitting element 10 of FIG. 1. In some embodiments, FIG. 7 is a cross sectional view exemplarily taken along line 1B-1B′ in FIG. 1. In some embodiments, FIG. 7 is a cross sectional view exemplarily taken along line 1B-1B′ in FIG. 1 and illustrating only a light emitting region. FIG. 7 has a structure similar to the structure of FIG. 2, with a difference described as follows.

In some embodiments, the substrate 100 has at least pixel regions R1 and R2, the pixel region R1 corresponds to the organic light emitting unit 101, and the pixel region R2 corresponds to the organic light emitting unit 102. In some embodiments, the pixel region R1 includes a sub-pixel region R1a, a sub-pixel region R1b, and a sub-pixel region R1c corresponding to an organic light emitting sub-unit 101a, an organic light emitting sub-unit 101b, and an organic light emitting sub-unit 101c, respectively. In some embodiments, the pixel region R2 includes a sub-pixel region R2a, a sub-pixel region R2b, and a sub-pixel region R2c corresponding to an organic light emitting sub-unit 102a, an organic light emitting sub-unit 102b, and an organic light emitting sub-unit 102c, respectively.

In some embodiments, the light emitting layer 20 includes an organic light emitting layer 260C. In some embodiments, the organic light emitting layer 260 includes a plurality of organic material layers, such as a hole injection layer 261, a hole transport layer 262, an electron blocking layer (EBL) 263, an organic emissive layer 264, an electron transport layer 265, and an electron injection layer 266.

In some embodiments, the organic light emitting element 10C includes reflective layers 281 and 282, the electrodes 215 and 225 are transparent electrodes, and the reflective layers 281 and 282 are disposed between the substrate 100 and the electrodes 215 and 225. In some embodiments, the reflective layers 281 and 282 include a non-conductive material, such as a distributed Bragg reflector (DBR). In some embodiments, the reflective layers 281 and 282 include a plurality of pairs of non-conductive material layers, and a refractive index difference between each pair of non-conductive material layers is equal to or greater than 0.2, such as equal to or greater than 0.4. In some embodiments, the reflective layers 281 and 282 include reflective surfaces 281a and 282a (also referred to as semi-reflective surfaces), and the electrode 216 includes a surface 2162 (also referred to as a fully reflective surface). In some embodiments, a light emitting surface of the organic light emitting element 10C is a surface 50a of a lens structure 50.

In some embodiments, for the light emitted from the organic light emitting layers 260A, 260B, and 260C, the surface 2162 (or the fully reflective surface) have a reflectance greater than a reflectance of the reflective surfaces 218a and 282a (or the semi-reflective surfaces). In some embodiments, for the light emitted from the organic light emitting layers 260A, 260B, and 260C, the reflective surfaces 218a and 282a have a reflectance greater than 20% and less than 80%, such as equal to or greater than 30%, equal to or greater than 40%, equal to or greater than 50%, equal to or greater than 60%, or equal to or greater than 70%. In some embodiments, for the light emitted from the organic light emitting layers 260A, 260B, and 260C, the surface 2162 has a reflectance greater than 90%, such as equal to or greater than 95%.

In some embodiments, for the light emitted from the organic light emitting layers 260A, 260B, and 260C, the surface 2162 (or the fully reflective surface) has a transmittance less than a transmittance of the reflective surfaces 218a and 282a (or the semi-reflective surfaces). In some embodiments, for the light emitted from the organic light emitting layers 260A, 260B, and 260C, the reflective surfaces 218a and 282a have a transmittance less than 80% and greater than 20%, such as equal to or less than 70%, equal to or less than 60%, equal to or less than 50%, equal to or less than 40%, or equal to or less than 30%. In some embodiments, for the light emitted from the organic light emitting layers 260A, 260B, and 260C, the surface 2162 has a transmittance less than 10%, such as less than 5%.

A distance between the semi-reflective surface (e.g., the reflective surfaces 281a and 282a) and the fully reflective surface (e.g., the surface 2162) constitutes or defines an optical cavity length (also referred to as a of a cavity length) of a microcavity or a micro resonance cavity. When the cavity length of the first order resonance cavity of the organic light emitting element 10C satisfies the aforementioned condition for N1 or the cavity length of the second order resonance cavity satisfies the aforementioned condition for N2, the luminous efficacy can be improved and the thickness of the entire structure of the organic light emitting element 10C can be reduced.

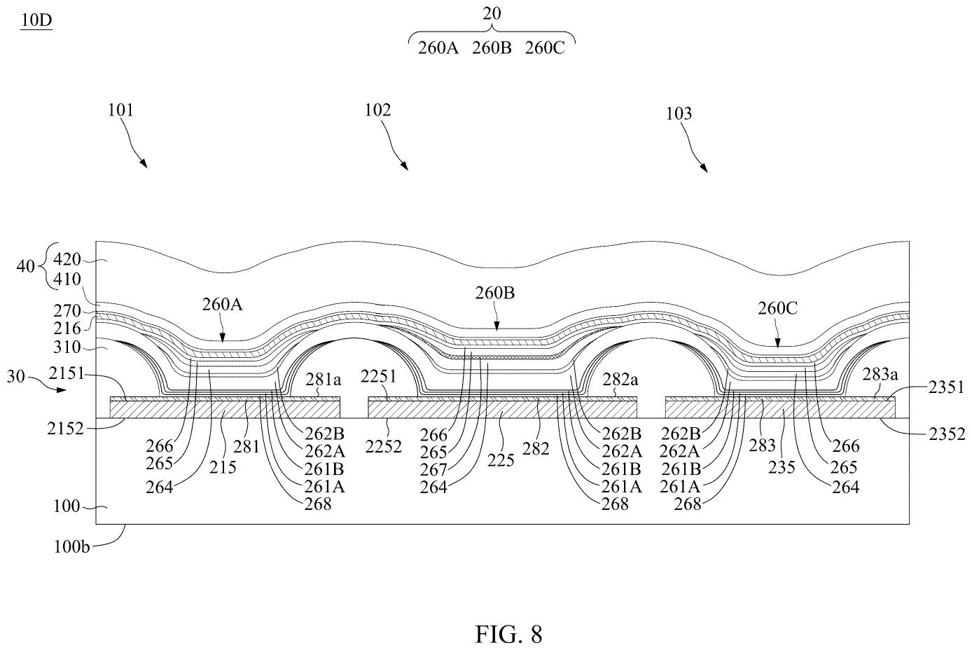

FIG. 8 is a cross sectional view exemplarily showing an organic light emitting element 10D. In some embodiments, FIG. 8 is a cross sectional view exemplarily showing the organic light emitting element 10 of FIG. 1. In some embodiments, FIG. 8 is a cross sectional view exemplarily taken along line 1B-1B′ in FIG. 1. In some embodiments, FIG. 8 is a cross sectional view exemplarily taken along line 1B-1B′ in FIG. 1 and illustrating only a light emitting region. FIG. 8 has a structure similar to the structure of FIG. 2, with a difference described as follows.

In some embodiments, the organic light emitting element 10D includes reflective layers 281, 282, and 283 further disposed between the organic light emitting layers 260A, 260B, and 260C and the electrodes 215, 225, and 235. In some embodiments, the reflective layers 281, 282, and 283 include reflective surfaces 282a, 282a, and 283a (also referred to as semi-reflective surfaces), the electrode 215 includes a surface 2151 (also referred to as a fully reflective surface) facing an organic light emitting layer, the electrode 225 includes a surface 2251 (also referred to as a fully reflective surface) facing an organic light emitting layer, and the electrode 235 includes a surface 2351 (also referred to as a fully reflective surface) facing an organic light emitting layer. In some embodiments, a light emitting surface of the organic light emitting element 10D is a surface 100b of the substrate 100.

In some embodiments, for the light emitted from the organic light emitting layers 260A, 260B, and 260C, the surfaces 2151, 2251, and 2351 (or the fully reflective surfaces) have a reflectance greater than a reflectance of the reflective surfaces 282a, 282a, and 283a (or the semi-reflective surfaces). In some embodiments, for the light emitted from the organic light emitting layers 260A, 260B, and 260C, the reflective surfaces 282a, 282a, and 283a have a reflectance greater than 20% and less than 80%, such as equal to or greater than 30%, equal to or greater than 40%, equal to or greater than 50%, equal to or greater than 60%, or equal to or greater than 70%. In some embodiments, for the light emitted from the organic light emitting layers 260A, 260B, and 260C, the surfaces 2151, 2251, and 2351 have a reflectance greater than 90%, such as equal to or greater than 95%.

In some embodiments, for the light emitted from the organic light emitting layers 260A, 260B, and 260C, the surfaces 2151, 2251, and 2351 (or the fully reflective surfaces) have a transmittance less than a transmittance of the reflective surfaces 282a, 282a, and 283a (or the semi-reflective surfaces). In some embodiments, for the light emitted from the organic light emitting layers 260A, 260B, and 260C, the reflective surfaces 282a, 282a, and 283a have a transmittance less than 80% and greater than 20%, such as equal to or less than 70%, equal to or less than 60%, equal to or less than 50%, equal to or less than 40%, or equal to or less than 30%. In some embodiments, for the light emitted from the organic light emitting layers 260A, 260B, and 260C, the surfaces 2151, 2251, and 2351 have a transmittance less than 10%, such as less than 5%.

A distance between the semi-reflective surface (e.g., the reflective surfaces 282a, 282a, and 283a) and the fully reflective surface (e.g., the surfaces 2151, 2251, and 2351) constitutes or defines an optical cavity length (also referred to as a of a cavity length) of a microcavity or a micro resonance cavity. When the cavity length of the first order resonance cavity of the organic light emitting element 10D satisfies the aforementioned condition for N1 or the cavity length of the second order resonance cavity satisfies the aforementioned condition for N2, the luminous efficacy can be improved and the thickness of the entire structure of the organic light emitting element 10D can be reduced.

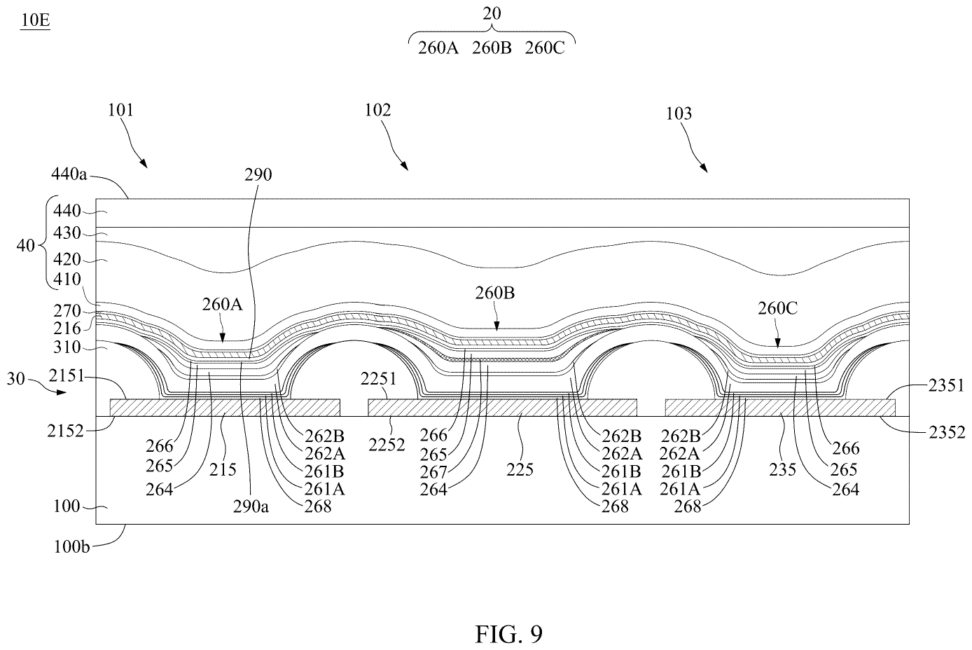

FIG. 9 is a cross sectional view exemplarily showing an organic light emitting element 10E. In some embodiments, FIG. 9 is a cross sectional view exemplarily showing the organic light emitting element 10 of FIG. 1. In some embodiments, FIG. 9 is a cross sectional view exemplarily taken along line 1B-1B′ in FIG. 1. In some embodiments, FIG. 9 is a cross sectional view exemplarily taken along line 1B-1B′ in FIG. 1 and illustrating only a light emitting region. FIG. 9 has a structure similar to the structure of FIG. 2, with a difference described as follows.

In some embodiments, the organic light emitting element 10E includes a reflective layer 290 further disposed between the organic light emitting layers 260A, 260B, and 260C and the electrode 216. In some embodiments, the reflective layer 290 includes a reflective surface 290a (also referred to as a semi-reflective surface), the electrode 215 includes a surface 2151 (also referred to as a fully reflective surface) facing an organic light emitting layer, the electrode 225 includes a surface 2251 (also referred to as a fully reflective surface) facing an organic light emitting layer, and the electrode 235 includes a surface 2351 (also referred to as a fully reflective surface) facing an organic light emitting layer. In some embodiments, a light emitting surface of the organic light emitting element 10E is a surface 440a of the cover plate 440.

In some embodiments, for the light emitted from the organic light emitting layers 260A, 260B, and 260C, the surfaces 2151, 2251, and 2351 (or the fully reflective surfaces) have a reflectance greater than a reflectance of the reflective surface 290a (or the semi-reflective surface). In some embodiments, for the light emitted from the organic light emitting layers 260A, 260B, and 260C, the reflective surface 290a has a reflectance greater than 20% and less than 80%, such as equal to or greater than 30%, equal to or greater than 40%, equal to or greater than 50%, equal to or greater than 60%, or equal to or greater than 70%. In some embodiments, for the light emitted from the organic light emitting layers 260A, 260B, and 260C, the surfaces 2151, 2251, and 2351 have a reflectance greater than 90%, such as equal to or greater than 95%.

In some embodiments, for the light emitted from the organic light emitting layers 260A, 260B, and 260C, the surfaces 2151, 2251, and 2351 (or the fully reflective surfaces) have a transmittance less than a transmittance of the reflective surface 290a (or the semi-reflective surface). In some embodiments, for the light emitted from the organic light emitting layers 260A, 260B, and 260C, the reflective surface 290a has a transmittance less than 80% and greater than 20%, such as equal to or less than 70%, equal to or less than 60%, equal to or less than 50%, equal to or less than 40%, or equal to or less than 30%. In some embodiments, for the light emitted from the organic light emitting layers 260A, 260B, and 260C, the surfaces 2151, 2251, and 2351 have a transmittance less than 10%, such as less than 5%.

A distance between the semi-reflective surface (e.g., the reflective surface 290a) and the fully reflective surface (e.g., the surfaces 2151, 2251, and 2351) constitutes or defines an optical cavity length (also referred to as a of a cavity length) of a microcavity or a micro resonance cavity. When the cavity length of the first order resonance cavity of the organic light emitting element 10E satisfies the aforementioned condition for N1 or the cavity length of the second order resonance cavity satisfies the aforementioned condition for N2, the luminous efficacy can be improved and the thickness of the entire structure of the organic light emitting element 10E can be reduced.

The aforementioned content generally outlines the features of some implementations, allowing one skilled in the art to better understand various aspects of the disclosure. One skilled in the art should understand that hid disclosure can be easily used as a foundation to design or modify other processes and structures to achieve the same objectives and/or attain the same advantages as the embodiments described in the present application. One skilled in the art should also understand that such equivalent structures do not depart from the spirit and the scope of the disclosed content, and various changes, substitutions, and modifications can be made without departing from the spirit and the scope of the disclosure.

What is claimed is:

1. An organic light emitting element, comprising:
a substrate;
an electrode disposed on the substrate;
a semi-reflective surface and a fully reflective surface; and
an organic light emitting layer disposed between the semi-reflective surface and the fully reflective surface;
wherein a distance between the semi-reflective surface and the fully reflective surface defines an optical cavity length of a micro resonance cavity, a half wavelength of light emitted from the organic light emitting layer is N1 times a cavity length of a first order resonance cavity of the organic light emitting element, and N1 is equal to or greater than 1 and less than 1.6.

2. The organic light emitting element according to claim 1, wherein when the organic light emitting layer emits red light, N1 is Nr, and when the organic light emitting layer emits green light, N1 is Nb, wherein Nb is greater than Nr.

3. The organic light emitting element according to claim 2, further comprising:
a reflective layer disposed on the substrate, the reflective layer comprising the semi-reflective surface, wherein Nb is 1 to 1.42 times Nr.

4. The organic light emitting element according to claim 1, further comprising:
a reflective layer disposed on the substrate, the reflective layer comprising a metal;
wherein when the organic light emitting layer emits red light, N1 is equal to or greater than 1.12 and equal to or less than 1.34, and when the organic light emitting layer emits green light, N1 is equal to or greater than 1.32 and equal to or less than 1.58.

5. The organic light emitting element according to claim 1, further comprising:
a reflective layer disposed on the substrate, the reflective layer comprising a dielectric;
wherein when the organic light emitting layer emits red light, N1 is equal to or greater than 1.00 and equal to or less than 1.17, and when the organic light emitting layer emits green light, N1 is equal to or greater than 1.02 and equal to or less than 1.23.

6. The organic light emitting element according to claim 1, wherein the electrode comprises a transparent conductive material.

7. The organic light emitting element according to claim 1, wherein the substrate comprises a transparent material.

8. The organic light emitting element according to claim 1, wherein for the light emitted from the organic light emitting layer, the semi-reflective surface has a reflectance greater than 20% and less than 80%, and the fully reflective surface has a reflectance greater than 90%.

9. An organic light emitting element, comprising:
a substrate;
an electrode disposed on the substrate;
a semi-reflective surface and a fully reflective surface; and
an organic light emitting layer disposed between the semi-reflective surface and the fully reflective surface, wherein a distance between the semi-reflective surface and the fully reflective surface defines an optical cavity length of a micro resonance cavity, a wavelength of light emitted from the organic light emitting layer is N2 times a cavity length of a second order resonance cavity of the organic light emitting element, and N2 is equal to or greater than 1 and less than 1.4.

10. The organic light emitting element according to claim 9, further comprising:
a reflective layer disposed on the substrate, the reflective layer comprising a composite metal;
wherein when the organic light emitting layer emits red light, N2 is equal to or greater than 1.05 and equal to or less than 1.24.

11. The organic light emitting element according to claim 9, further comprising:
a reflective layer disposed on the substrate, the reflective layer comprising a composite metal;
wherein when the organic light emitting layer emits green light, N2 is equal to or greater than 1.12 and equal to or less than 1.33.

12. The organic light emitting element according to claim 9, further comprising:
a reflective layer disposed on the substrate, the reflective layer comprising a plurality of pairs of non-conductive material layers;
wherein when the organic light emitting layer emits red light, N2 is equal to or greater than 1.00 and equal to or less than 1.19.

13. The organic light emitting element according to claim 9, further comprising:
a reflective layer disposed on the substrate, the reflective layer comprising a plurality of pairs of non-conductive material layers;
wherein when the organic light emitting layer emits green light, N2 is equal to or greater than 1.04 and equal to or less than 1.24.

14. The organic light emitting element according to claim 9, wherein the electrode is a metal electrode.

15. The organic light emitting element according to claim 9, wherein the electrode is a transparent electrode.

16. The organic light emitting element according to claim 9, wherein for the light emitted from the organic light emitting layer, the semi-reflective surface has a transmittance less than 80% and greater than 20%, and the fully reflective surface has a transmittance less than 10%.

17. The organic light emitting element according to claim 9, wherein the organic light emitting layer comprises one of a hole injection layer, a hole transport layer, an organic emissive layer, an electron transport layer, or an electron injection layer.
